(19) United States
(12) Patent Application Publication
(10) Pub. No.: US 2021/0083135 A1
(43) Pub. Date: Mar. 18, 2021

(54) PASSIVATED CONTACT INTERLAYER FOR PHOTOVOLTAICS

(71) Applicants: Alliance for Sustainable Energy, LLC, Golden, CO (US); Colorado School of Mines, Golden, CO (US)

(72) Inventors: Pauls STRADINS, Golden, CO (US); William Michael NEMETH, Wheat Ridge, CO (US); Sumit AGARWAL, Arvada, CO (US)

(21) Appl. No.: 17/020,115

(22) Filed: Sep. 14, 2020

Related U.S. Application Data
(60) Provisional application No. 62/899,795, filed on Sep. 13, 2019.

(51) Int. Cl. H01L 31/0747; H01L 31/20

(52) U.S. Cl. CPC H01L 31/0747; H01L 31/208; H01L 31/202

(57) ABSTRACT

The present disclosure provides systems and methods for improving the performance of a silicon solar cell by improving the contact layer. This involves chemically bonding an interlayer to the dielectric layer. An interlayer introduces specific impurities into the passivated contact. These impurities (such as nitrogen, fluorine, and/or carbon) can improve the passivation of the contact by improving or rejecting adhesion.

### CROSS-REFERENCE TO RELATED APPLICATIONS

This application claims priority to U.S. Provisional Patent Application No. 62/899,795 filed on Sep. 13, 2019, the contents of which are incorporated herein by reference in its entirety.

### CONTRACTUAL ORIGIN

The United States Government has rights in this invention under Contract No. DE-AC36-08G028308 between the United States Department of Energy and Alliance for Sustainable Energy, LLC, the Manager and Operator of the National Renewable Energy Laboratory.

### BACKGROUND

A recent improvement in silicon solar cell manufacturing is the use of passivated contacts, wherein a thin leaky dielectric layer is placed between a silicon wafer and a semiconductor layer, mitigating subsequent metallization damage. The dielectric layer provides the necessary bonding to the silicon wafer for effective chemical passivation via dangling bond occupation. A key performance factor of a silicon solar cell is the effective prevention of metal from reaching the silicon wafer, where layer defects or metal diffusion paths, such as blisters or pinholes, can cause operational problems. The dielectric layer must therefore provide the appropriate bonding environment for the deposition and subsequent processing of the semiconductor layer for proper adhesion. However, current technologies fail to meet these needs and, therefore, there remains a need for improved silicon solar cells and methods for manufacturing these important devices.

### SUMMARY

In a first aspect, a device including a silicon layer, a dielectric layer in direct contact with the silicon layer, an interlayer in direct contact with the dielectric layer, and a precursor semiconductor layer, where the interlayer includes a functional group, and an impurity, the dielectric layer includes a dielectric material and the impurity, the functional group is bonded to the dielectric layer, and the precursor semiconductor layer includes a semiconductor material and the impurity. In some embodiments, the dielectric layer includes tunneling silicon dioxide. In some embodiments, the functional group includes trimethylsilyl. In some embodiments, the precursor semiconductor layer includes an amorphous silicon. In some embodiments, the silicon layer is a preferred float zone silicon wafer. In some embodiments, the silicon layer is an n-type Czochralski textured silicon wafer. In some embodiments, the device has a contact resistivity of approximately 5 mΩ-cm². In some embodiments, the impurity includes at least one of carbon, nitrogen, or fluorine.

In a second aspect, a method of forming a photovoltaic cell includes depositing a dielectric layer on a silicon layer, applying a first precursor to the dielectric layer, resulting in an interlayer in direct contact with the dielectric layer, applying a second precursor to the interlayer, resulting in a first layer in direct contact with the interlayer, and annealing the dielectric layer, the interlayer, and the first layer, resulting in the first layer being transformed to a semiconductor layer, where the photovoltaic cell includes the silicon layer, the dielectric layer, the interlayer, and the semiconductor layer. In some embodiments, the dielectric layer includes a tunneling silicon dioxide. In some embodiments, the applying of the first precursor to the dielectric layer includes immersing the silicon layer in a first precursor. In some embodiments, the applying of the first precursor to the dielectric layer includes suspending the silicon layer over the first precursor. In some embodiments, the second precursor includes silane, hydrogen, phosphine, and/or diborane gases. In some embodiments, the first layer includes an amorphous silicon, and the semiconductor layer includes a polycrystalline silicon. In some embodiments, the first precursor includes a silane. In some embodiments, the silane is hexamethyldisilazane (HMDS), diemthylaminothrimethylsilane (DMATMS), or aminopropyltrimethoxysilane (APTMS). In some embodiments, the method also includes diffusing an impurity into the dielectric layer, and the interlayer includes a functional group and the impurity, and the functional group bonds with the dielectric layer. In some embodiments, the method also includes diffusing an impurity into the first layer. In some embodiments, the impurity includes at least one of carbon, nitrogen, or fluorine. In some embodiments, the functional group includes trimethylsilyl.

### BRIEF DESCRIPTION OF THE DRAWINGS

Exemplary embodiments are illustrated in the referenced figures of the drawings. In it is intended that the embodiments and figures disclosed herein are considered to be illustrative rather than limiting.

FIG. 1 illustrates a photovoltaic cell half-stack, including intermediary stacks, according to some embodiments of the present disclosure.

FIG. 2 illustrates a method for making the photovoltaic cell according to some embodiments of the present disclosure.

FIG. 3 illustrates an exemplary process of applying an interlayer to a passivated contact, according to some embodiments of the present disclosure.

FIG. 4A is a photograph of a silicon wafer with a silicon dioxide dielectric layer. FIG. 4B is a photograph of a silicon wafer with a silicon dioxide dielectric layer that was treated with HMDS as an interlayer precursor.

FIG. 5A is a photograph of a silicon wafer with a silicon dioxide dielectric layer. FIG. 5B is a photograph of a silicon wafer with a dielectric layer of silicon dioxide that was treated with N dimethylaminotrimethylsilane (DMATMS) as an interlayer precursor.

FIG. 6A is a photograph of a silicon wafer with a silicon dioxide dielectric layer that was treated with hexamethyldisilazane (HMDS) as an interlayer precursor then treated with ultra-violet ozone (UV-O₃), resulting in a patterned interlayer. FIG. 6B is a photograph of a silicon wafer with a silicon dioxide dielectric layer that was treated with HMDS as an interlayer precursor then treated with UV-O₃, resulting in a patterned interlayer after rinsing with deionized water.

FIG. 7 illustrates the time-of-flight secondary ion mass spectroscopy (ToF-SIMS) spectra of a positive polycrystalline silicon (p/poly-Si) passivated contact.

FIG. 8A is a photograph of a silicon wafer with a silicon dioxide dielectric layer that was treated with DMATMS as an interlayer precursor for 0 minutes. FIG. 8B is a photograph of a silicon wafer with a silicon dioxide dielectric layer that was treated with DMATMS as an interlayer precursor for 1 minute. FIG. 8C is a photograph of a silicon wafer with a silicon dioxide dielectric layer that was treated with DMATMS as an interlayer precursor for 10 minutes. FIG. 8D is a photograph of a silicon wafer with a silicon dioxide dielectric layer that was treated with DMATMS as an interlayer precursor for 100 minutes.

FIG. 9 illustrates the functionalized film thickness dependence on immersion time in an interlayer, according to some embodiments of the present disclosure.

### REFERENCE NUMERALS

100 . . . photovoltaic half-stack
105 . . . silicon wafer
110 . . . dielectric layer
115 . . . interlayer precursor
120 . . . interlayer
125 . . . leaving group
130 . . . a method of deposition
135 . . . amorphous silicon
140 . . . heat
145 . . . polycrystalline silicon layer
200 . . . method of making a photovoltaic half-stack
205 . . . coating
210 . . . applying
215 . . . depositing
220 . . . annealing
300 . . . exemplary process
305 . . . PV half stack
310 . . . hydroxyl group
315 . . . applying an interlayer precursor
320 . . . functional group

### DETAILED DESCRIPTION

The following embodiments and aspects thereof are described and illustrated in conjunction with systems, tools, and methods that are meant to be exemplary and illustrative, not limiting in scope. In various embodiments, one or more of the above-described problems have been reduced or eliminated, while other embodiments are directed to other improvements.

The present disclosure provides systems and methods for improving the performance of a photovoltaic cell by introducing an additional layer, or interlayer, into the passivated contact. This involves chemically bonding an interlayer to the dielectric layer. The interlayer introduces specific impurities into the passivated contact, which can improve the performance of the photovoltaic cell by altering the adherence of the semiconductor layer and/or dielectric layer. The interlayer is a permanent or temporary layer deposited on the dielectric layer, which allows impurities to diffuse into both the dielectric layer and a semiconductor precursor layer. These impurities may be elements or compounds which can improve the features of the photovoltaic cell.

In some embodiments, the interlayer may be deposited onto the dielectric layer using an interlayer precursor in vapor or liquid form. The interlayer bonds to the dielectric surface using an exchange mechanism, where a leaving group is formed from hydrogen and/or hydroxyl groups present on the dielectric surface and a sacrificial group of the interlayer precursor. This allows the desired components of the interlayer to attach to the dielectric layer and for the interlayer to terminate with a desired functional group. Once attached to the dielectric layer, this functional group of the interlayer provides a stable anchor for the application of the semiconductor layer, chemical resistance to etching or blistering by the dielectric layer, and/or may be used as a functional layer in the photovoltaic device. The interlayer may improve the yield and uniformity of the dielectric layer, widen the process window of the semiconductor layer, and/or chemically manipulate the dielectric/semiconductor interface to promote carrier transport while maintaining passivation.

In some embodiments, the selection of an interlayer may be made based on the desired outcome for the photovoltaic cell. For example, in some embodiments, the addition of an interlayer on the dielectric surface may promote adhesion of the silicon wafer, preventing blistering and/or cracking of the films attached to the silicon wafer. In other embodiments, the addition of an interlayer on the dielectric surface may promote rejection of films attaching to the silicon wafer, to allow for patterning of the photovoltaic cell. Adhesion or rejection is governed by the chemical activity of the functional groups on the end of the attached interlayers.

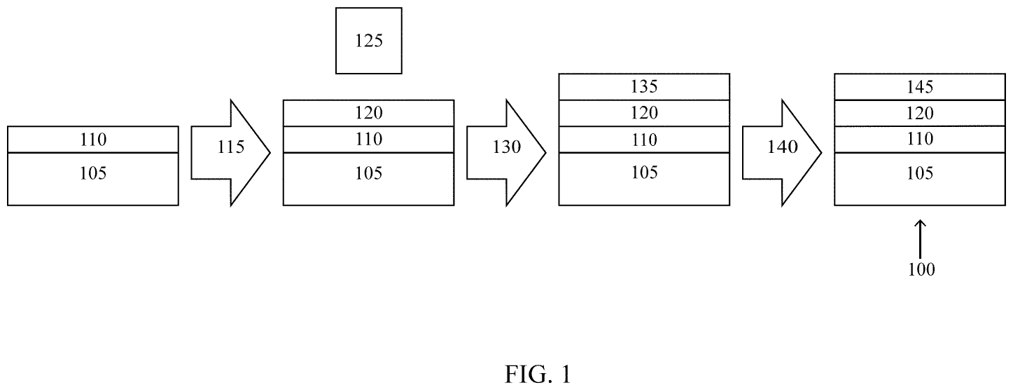

FIG. 1 illustrates a photovoltaic half-stack, including intermediary stacks, according to some embodiments of the present disclosure. The photovoltaic half-stack 100 is made of a silicon wafer 105, a dielectric layer 110, an interlayer 120, and a semiconductor 145. Initially, a dielectric layer 110 is deposited on the silicon wafer 105, then an interlayer precursor 115 is applied, resulting in the interlayer 120 covering the dielectric layer 110. A leaving group 125 may exist outside of this intermediary stack as a result of a reaction between the interlayer precursor 115 and the dielectric layer 110. A method of deposition 130 deposits a layer of semiconductor precursor 135, which is transformed using heat 140 into a semiconductor 145. In some embodiments, the silicon wafer 105 may be a preferred float zone (pFz) silicon wafer, an n-type Czochralski textured (nCz) silicon wafer, a single-crystalline p-type silicon wafer, a monocrystalline silicon wafer, polycrystalline silicon wafer, a silicon sheets from power (SSP) wafer, or other type of silicon wafer suitable for photovoltaic cells. In some embodiments, the dielectric layer 110 may be silicon dioxide (SiO₂), non- or lightly doped hydrogenated amorphous silicon (i/a-Si:H), silicon nitride (SiNₓ), and/or aluminum oxide (Al₂O₃). In some embodiments, the interlayer 120 may be trimethylsilyl (Si(CH₃)₃, triethylamine (N(CH₂CH₃)₃), a silyl ether, and/or a silicone. In some embodiments, the interlayer 120 may contain carbon (C), nitrogen (N), boron (B), fluorine (F), chlorine (CO, oxygen (O), sulfur (S), phosphorous (P), silicon (Si), and/or aluminum (Al) in elemental form or in a compound. The leaving group 125 may be ammonia (NH₄), methane (CH₄), ethane (C₂H₆), methanol (CH₃OH), water, or other compound containing components of the interlayer precursor 115 and the dielectric layer 110. In some embodiments, the interlayer precursor 115 may be hexamethyldisilazane (HMDS), dimethylaminotrimethylsilane (DMATMS), 3-aminopropyltrimethoxysilane (APTMS) and/or a silane compound. In some embodiments the interlayer precursor 115 may contain a methyl-, ethyl, amino-, and/or silane group in larger chain. The interlayer precursor 115 may be a self-assembled monolayer (SAM). In some embodiments, the semiconductor precursor 135 may be amorphous silicon, monocrystalline silicon, polycrystalline silicon, and/or another semiconductor material. In some embodiments, the semiconductor 145 may be amorphous silicon, monocrystalline silicon, polycrystalline silicon, and/or another semiconductor material.

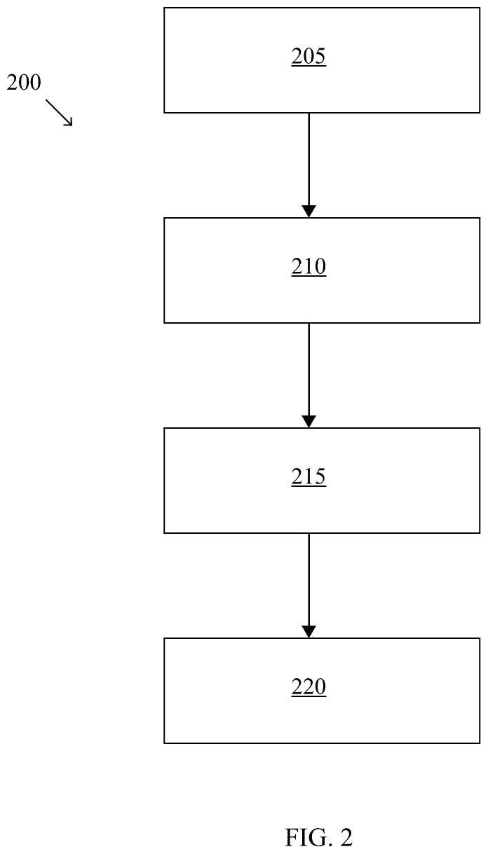

FIG. 2 illustrates a method for making the photovoltaic device according to some embodiments of the present disclosure. The method 200 of making the photovoltaic device begins by coating 205 a silicon wafer 105 with a dielectric layer 110. This may be done using traditional methods to prepare a photovoltaic device, which may include preparing a silicon wafer by cleaning it in SC-1 and/or SC-2 solutions, dipping the silicon wafer 105 in hydrofluoric acid (HF) solution to remove any chemical oxide, and annealing the silicon wafer 105 with a flowing nitrogen gas (N₂) and oxygen (02) mixture to grow the dielectric layer. In some embodiments, when the dielectric layer 110 is silicon dioxide, hydroxyl (OH⁻) groups may be present on the surface of the dielectric layer 110. In some embodiments, the silicon wafer may be a preferred float zone (pFz) silicon wafer. In some embodiments, the silicon wafer 105 may be an n-type Czochralski textured (nCz) silicon wafer.

Next, the method 200 of making the photovoltaic device includes applying 210 an interlayer precursor 115. The interlayer precursor 115 may be applied using plasma-enhanced chemical vapor deposition (PECVD), static vapor deposition, atomic layer deposition, basic vapor deposition, liquid immersion, and/or other deposition technique. The applying 210 of an interlayer precursor 115 results in the formation of an interlayer 120 on the dielectric layer 110. In some embodiments, the interlayer precursor 115 may be an aminosilane, chlorosilane, alkoxysilane, alkene, carboxylate, and/or an amine-based compound. In some embodiments, the interlayer precursor 115 deposits the interlayer 120, and a functional group of the interlayer precursor 115 bonds to the oxygen of the hydroxyl groups, releasing the hydrogen of the hydroxyl groups to bond with the remainder of the interlayer precursor 115, creating a leaving group. For example, in FIG. 1, if the interlayer precursor 115 is hexamethyldisilazane (HMDS), the leaving group 125 is ammonia (NH₃), which is released when HMDS bonds with an hydroxyl group on the surface of the tunneling silicon dioxide dielectric layer 110. In this example, the interlayer 120 contains trimethylsilyl (Si(CH₃)₃) and triethylamine (N(CH₂CH₃)₃) functional groups attached to oxygen molecules in the dielectric layer. In some embodiments, the interlayer 120 may contain methyl-, amino-, and/or fluoro-groups as functional groups. The interlayer 120 may be a self-assembled monolayer (SAM), which may bond with the surface of the dielectric layer 110 and terminate with a functional group.

Next, the method 200 of making the photovoltaic device 100 includes depositing 215 a semiconductor layer precursor 135 onto the interlayer 120, resulting in the forming of a semiconductor layer 145 on the interlayer 120. In some embodiments the semiconductor layer 145 may be deposited using plasma-enhanced chemical vapor deposition (PECVD), static vapor deposition, atomic layer deposition, basic vapor deposition, liquid immersion, and/or other deposition technique. For example, in FIG. 1, PECVD 130 is used to deposit a semiconductor precursor 135 (in this example, the semiconductor precursor was amorphous silicon) on the interlayer 120. The semiconductor precursor 135 can be deposited using a variety of gases, such as of silane (SiH₄), hydrogen (H₂), phosphine (PH₃), and/or diborane (B₂H₆).

Next, the method 200 of making the photovoltaic device includes annealing 220 the photovoltaic device 100. For example, in FIG. 1, annealing 220 results in the transformation of a semiconductor precursor 135 of amorphous silicon to a semiconductor 145 of polycrystalline silicon. This may be done by annealing 220 the layers in a tube furnace at very high temperatures (such as 850° C.) to crystallize the amorphous silicon into polycrystalline silicon. The passivated contact may then be hydrogenated. In some embodiments, the silicon wafer 105 may also be coated with atomic layer deposited aluminum oxide (Al₂O₃) and annealed a second time at a lower temperature (such as 400° C.) for hydrogenation which is removed with a hydrofluoric acid dip.

In some embodiments, depositing 215 a semiconductor precursor 135 and annealing 220 the photovoltaic device 100 may be performed as with traditional photovoltaic cell manufacturing practices. That is, in some embodiments, the integration of the interlayer 120 into the photovoltaic cell 100 does not alter the traditional manufacture process after the applying 210 of the interlayer precursor 115.

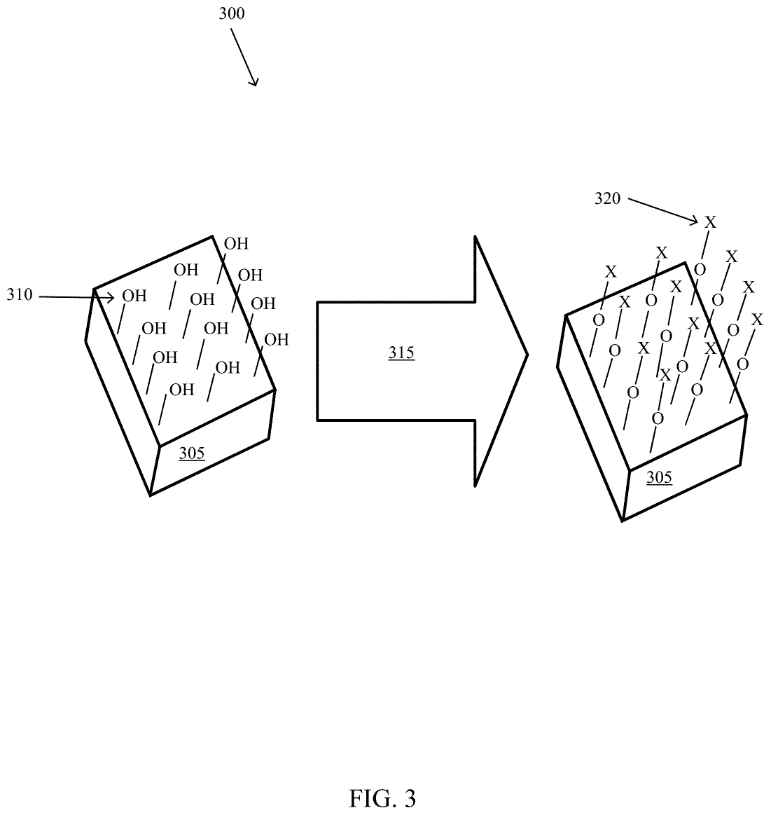

FIG. 3 illustrates details of an exemplary applying 210 of an interlayer 120 to a passivated contact, according to some embodiments of the present disclosure. The exemplary applying 210 of an interlayer 120 employed a semiconductor 145 of heavily boron doped p/poly-Si on a dielectric layer 110 of tunneling silicon dioxide to create a passivated contact. The silicon wafer (polished, Topsil 2 Ω-cm pFZ) was cleaned in SC-1 and SC-2 solutions then subjected to a 700° C. anneal in a tube furnace with flowing nitrogen and oxygen gas mixture to grow the dielectric layer, forming the PV half stack 305. The surface of the dielectric layer 110 had a p-hydroxyl (OH⁻) groups 310. Next, the hydroxyl-group functionalized surface of the dielectric layer 110 was exposed to an interlayer precursor 115 of hexamethyldisilazane (HMDS) vapor at room temperature in an enclosed PTFE container for approximately five (5) minutes 315. The functional group 320 (trimethylsilyl) of HMDS bonded to the oxygen of the hydroxyl groups 310. The result is a layer of functional groups 320 on the PV half stack 305. This layer of functional groups (or an interlayer) may improve the performance of the photovoltaic cell 100 by introducing specific impurities into the passivated contact through diffusion into the dielectric layer and/or the precursor semiconductor layer. The passivated contact is completed with the addition of a semiconductor layer (not shown in FIG. 3).

To create the semiconductor layer, precursor p-type (i.e., boron doped) amorphous silicon (a-Si:H) layers were deposited on the dielectric layer via 13.56 Hz RF plasma-enhanced chemical vapor deposition (PECVD) as using silane (SiH₄), hydrogen (H₂), and diborane (B₂H₆) gases at a pressure of 1 Torr. The resulting precursor photovoltaic device was then annealed in a tube furnace at 850° C. to crystallize the p-type a-Si:H into p-type polycrystalline silicon (poly-Si) (i.e., the semiconductor layer). The photovoltaic device was then coated with atomic layer deposited aluminum oxide (Al₂O₃) and annealed at 400° C. for hydrogenation, which is removed with a HF dip.

In some embodiments, the interlayer may introduce specific impurities into the dielectric layer and/or the semiconductor layer of the passivated contact through diffusion of impurities from the interlayer into the dielectric layer and/or the semiconductor layer. For example, using an interlayer precursor of HMDS forms and interlayer containing trimethylsilyl (Si(CH₃)₃ and/or triethylamine (N(CH₂CH₃)₃) functional groups bonded to oxygen in the dielectric layer. Through diffusion, impurities of nitrogen (N), fluorine (F), and/or carbon (C) may diffuse into the dielectric layer and/or the semiconductor layer from this interlayer. Having N diffuse into a dielectric layer of silicon dioxide and F and/or C diffuse into a semiconductor layer of poly-Si, may improve passivation of p-type poly-Si semiconductor layers, and thus the performance of the photovoltaic cell. Utilizing the methods described herein, these impurities may be delivered to the dielectric layer and/or the semiconductor layer of the passivated contact at high local (i.e., monolayer) concentrations, forming an interlayer.

In some embodiments, the addition of an interlayer on the dielectric layer may result in selective or improved adhesion between a silicon wafer (e.g., constructed of a-Si:H) and a dielectric layer (e.g., tunneling silicon dioxide), and a semiconductor layer (e.g., a-Si:H, and/or poly-Si). The interlayer may be a self-assembled monolayer (SAM). A SAM is the assembly of molecules without guidance from an external source to make itself into an organized monolayer on a surface. The formation of a SAM is mediated by a specific functional group that has a strong affinity for a particular surface. In the present disclosure, the SAMs used as interlayers may be selected based on their affinity for the dielectric layer and/or semiconductor layer (or semiconductor layer precursor).

In some embodiments, the methods described herein may influence dopant diffusion during crystallization of a-Si:H (a precursor semiconductor layer) into poly-Si (a semiconductor layer). The response to dopant diffusion is governed by the chemical activity of the end groups of the attached interlayers. For example, nitrogen in the interlayer may prevent boron (B) diffusion and fluorine (F) in the interlayer may promote boron diffusion in the semiconductor layer.

In some embodiments, an interlayer precursor of hexamethyldisilazane (HN[Si(CH₃)₃]₂, (HMDS)) may be used. A silicon wafer with an attached dielectric layer may be immersed in a liquid HMDS/toluene mixture then dried with nitrogen gas (N₂). Separately or in conjunction with liquid immersion, the silicon wafer with an attached dielectric layer may be held above liquid HMDS in an enclosed space (such as a polytetrafluoroethylene (PTFE) beaker) for static vapor application. Other examples of interlayer precursors include dimethylaminotrimethylsilane (DMATMS), 3-aminopropyltrimethoxysilane (APTMS), polyethylenimine (PEI), polyethylenimine ethoxylated (PEIE), and/or polydimethylsioxane (PDMS). In some embodiments, the silicon wafer may be a preferred float zone (pFZ) silicon wafer or a n-type Czochralski textured (nCz) silicon wafer.

Growing well-adhered semiconductor layers (such as poly-Si films) on the dielectric layer presents a challenge due to the blistering at the interface of these two layers. Most of the surface bonds in the disordered, semiconductor layer precursor of amorphous silicon layer are self-satisfied and few surface dangling bonds are available for the strong adhesion of the vapor deposited p-type a-Si:H. Also, specifically for PECVD deposition temperature is relatively low, which also likely reduces the layer adhesion. Lower temperature PECVD offers an advantage over low pressure chemical vapor deposition (LPCVD) poly-Si films because PECVD is single-sided, whereas the higher temperature LPCVD growth results in undesirable dual side deposition. Furthermore, the PECVD deposited a-Si:H films typically contain ˜10% hydrogen. This interstitial hydrogen diffuses and agglomerates during the growth and annealing, thus further decreasing a-Si:H adhesion. By modifying the dielectric layer (for example, tunneling silicon dioxide) surface with a interlayer, the hydroxyl groups on the dielectric layer react and anchor the functional silane interlayer group, which can be tailored with a variety of chemistries and complexities with the basic building blocks of methyl-, amino-, and/or fluoro-groups depending on desired characteristics.

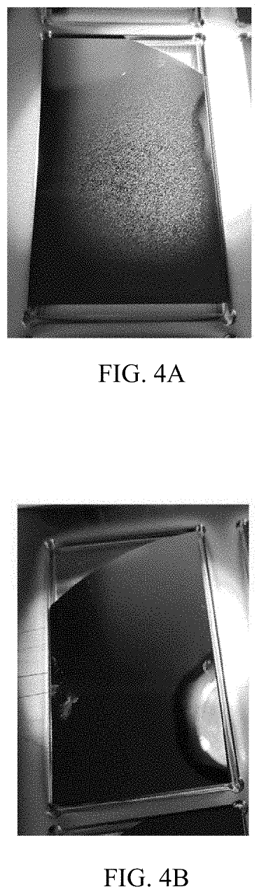

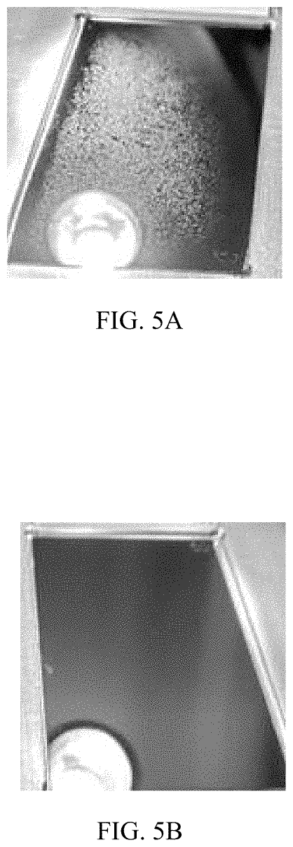

After functionalization with a interlayer (in this example, HMDS), p-type a-Si:H film was deposited on the functionalized dielectric layer and annealed it to 850° C. to crystallize into a poly-Si contact layer. Severe blistering of p/a-Si:H on untreated SiO₂ was observed (as shown in FIG. 4 and FIG. 5) and almost none on the silicon wafers treated with HMDS. Previously, the direct deposition of p/poly-Si has not worked on wafers due to blistering. However, utilizing the methods described herein and an interlayer to functionalize the surface, direct deposition of p/poly-Si can be performed. In the present disclosure, a p-type a-Si:H film was deposited with little or no blistering, then crystallized. The method described herein resulted in non-blistered, direct-deposited p/poly-Si contact.

In one example, lifetime measurements reveal similar recombination prefactor Jₒ values of 21 fA/cm² for HMDS treated silicon wafers versus 19 fA/cm² for non-treated silicon wafers, indicating that interlayer application does not negatively affect the passivation at the surface of the wafer. Furthermore, contact resistivities of HMDS treated wafers were 5.1 mΩ-cm² versus 38 mΩ-cm² for the nontreated wafers prior to metal pad isolation etch. This measurement accounts for metal-to-p/poly-Si as well as p/poly-Si-to-SiO₂/cSi. After isolation etch, the true contact resistivity of the metallized passivated contact to the cSi was 5.4 mΩ-cm² for the HMDS treated wafer, whereas the untreated wafer was non-linear presumably due to direct metal contact to the cSi wafer through blisters.

The use of interlayer precursors, such as HMDS, as described herein may be varied based on several features, including the use of HF microchannels, selective deposition, the use of dip in/spin-on dopant, and the use of a selective metal.

FIG. 4A is a photograph of a silicon wafer with a silicon dioxide dielectric layer. FIG. 4B is a photograph of a silicon wafer with a silicon dioxide dielectric layer that was treated with HMDS as an interlayer precursor. Both silicon wafers in FIG. 4A and FIG. 4B have a p/a-Si:H capping layer. The interlayer precursor on both silicon wafers in FIG. 4A and FIG. 4B was applied using static vapor application. FIGS. 4A and 4B show how the use of an interlayer precursor to functionalize the surface of a silicon wafer with an interlayer results in improved adhesion and less blistering of the dielectric layer (in FIGS. 4A and 4B the dielectric layer was tunneling silicon dioxide). The interlayer functional group resulting from using HMDS as an interlayer precursor is trimethylsilyl (Si(CH₃)₃). The presence of carbon (C) in the interlayer improves the adhesion and reduces blistering in the dielectric layer.

As shown in FIGS. 4A and 4B, two silicon wafers were cleaned in SC-1 and SC-2 solutions then dipped in hydrogen fluoride (HF) solution to remove the chemical oxide. One of the silicon wafers was subjected to a 700° C. anneal in a tube furnace with flowing nitrogen/oxygen (N₂/O₂) gas mixture to grow the silicon dioxide dielectric layer. interlayer precursors were then applied to some of this silicon wafers in liquid and/or vapor form. Liquid immersion proceeded in a HMDS/toluene mixture, then the silicon wafer was removed, and dried with N₂. In tandem to this liquid phase approach, the silicon wafer was placed in a PTFE beaker and suspended above 10 mL of pure HMDS for a static vapor application. The silicon wafer was held above the liquid and enclosed for 10 minutes at room temperature to allow for vapor application of the interlayer. Next, a precursor a-Si:H semiconductor layer was deposited on the silicon wafer via 13.56 MHz RF plasma enhanced chemical vapor deposition (PECVD) using a combination of silane (SiH₄), hydrogen (H₂), phosphine (PH₃), and diborane (B₂H₆) gases at a pressure of 1 Torr. The resulting photovoltaic device was then annealed in a tube furnace at 850° C. to crystalize the precursor semiconductor layer of a-Si:H into a semiconductor layer of poly-Si. The photovoltaic device was then coated with atomic-layer-deposited Al₂O₃ and annealed at 400° C. for hydrogenation, which was removed with a HF dip.

The PECVD growth of the precursor semiconductor layer of a-Si:H on a dielectric layer of tunneling silicon dioxide is highly process dependent where film delamination and blistering can occur. Using lower temperature PECVD or poly-Si films offers the advantage that it is inherently single-sided, whereas the higher temperature low-pressure chemical vapor deposition (LPCVD) growth results in undesirable dual side deposition. Conversely, LPCVD poly-Si films contain much less hydrogen due to immediate effusion as the film is deposited, while lower temperature PECVD films typically contain 10-15% hydrogen. Further, hydrogen diffuses and coalesces during the growth and annealing further decreasing a-Si:H adhesion. By modifying the surface with an interlayer, functional silane interlayer groups can be tailored with a variety of chemistries and complexities with the basic building blocks of methyl-, amino-, and/or fluoro-groups depending on desired characteristics.

FIG. 5A is a photograph of a silicon wafer with a silicon dioxide dielectric layer. FIG. 5B is a photograph of a silicon wafer with a dielectric layer of silicon dioxide that was treated with dimethylaminotrimethylsilane (DMATMS) as an interlayer precursor. FIG. 5A shows severe blistering of p/a-Si:H on a dielectric layer of silicon dioxide, whereas FIG. 5B shows almost no blistering of p/a-Si:H on a dielectric layer of silicon dioxide when the dielectric layer is treated with an interlayer precursor of DMATMS. The functional group of the interlayer with an interlayer precursor of DMATMS is trimethylsilyl (Si(CH₃)₃). In some embodiments, interlayer precursors may be a HMDS/toluene mixture, a DMATMS/chloroform mixture, and/or 3-aminopropyltrimethoxysilane (APTMS)/toluene mixture.

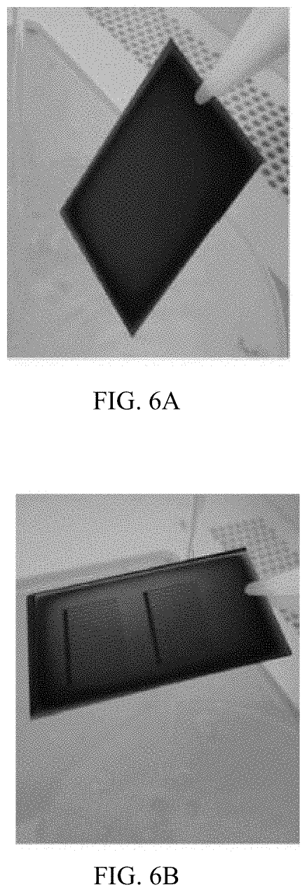

In some embodiments, an ultraviolet-ozone (UV-O₃) treatment can be used for patterning of interlayer-functionalized dielectric layer surface. This may be used to oxidize the interlayer optically. This is an example of how the use of an interlayer in construction of a photovoltaic cell can increase the ability to tailor the dielectric layer. For example, a UV-O₃ treatment and a shadow mask can be used after the process for manufacturing a photovoltaic cell using a interlayer is completed (i.e., after the photovoltaic cell is annealed), resulting in a pattered silicon wafer surface. FIG. 6A is a photograph of a silicon wafer with a silicon dioxide dielectric layer that was treated with HMDS as an interlayer precursor then treated with UV-O₃, resulting in a patterned interlayer. FIG. 6B is a photograph of a silicon wafer with a silicon dioxide dielectric layer that was treated with HMDS as an interlayer precursor then treated with UV-O₃, resulting in a patterned interlayer after rinsing with deionized water. The wetted pattern is clearly visible in FIG. 6B, corresponding to the UV-exposed areas. This approach may bypass the need for lithography for complicated structures such as interdigitated back contact solar cells. Using patterned interlayers' wettability allows dopant ink to selectively adhere to the surface of a semiconductor, such as poly-Si.

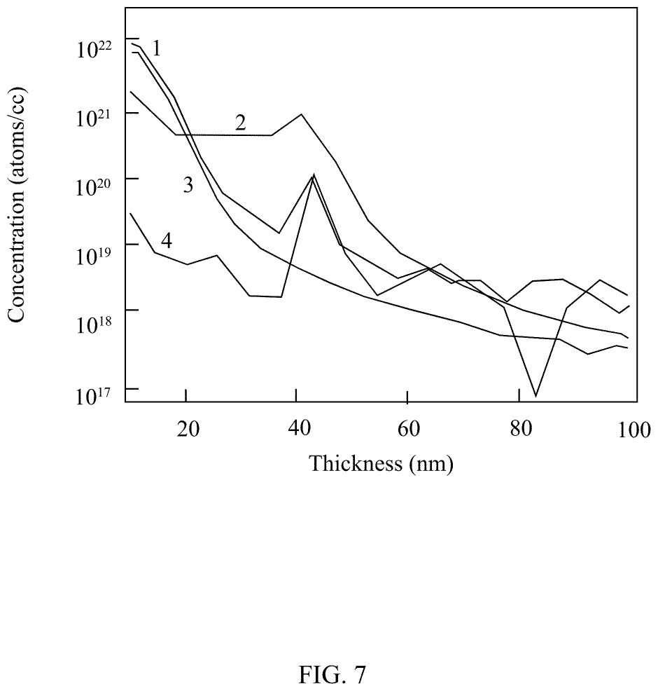

FIG. 7 illustrates the time-of-flight secondary ion mass spectroscopy (ToF-SIMS) spectra of a p/poly-Si passivated contact. Line 1 shows carbon in a p/a-Si:H, line 2 shows boron in a poly-Si, line 3 shows boron in p/a-Si:H, and line 4 shows carbon in a poly-Si. FIG. 7 indicates carbon located at the semiconductor layer/dielectric layer (in this example, poly-Si is the semiconductor layer and silicon dioxide is the dielectric layer) before and after the high temperature anneal of the photovoltaic cell. The improved adhesion may be because of this carbon. The carbon is present because of the interlayer from the interlayer precursor of HMDS. The carbon does not leave the interface with the anneal, indicating the presence of an interlayer in the final photovoltaic cell.

Water contact angle (WCA) measurements on polished wafers show 34° to 81.2° before and after HMDS application (with 72.4° on a hydrophobic, hydrogen terminated, hydrofluoric acid dipped untreated reference silicon wafer). The HMDS treated silicon wafer showed 708 mV iVoc, while the untreated was 692 mV. The finished double side textured devices deviated significantly, where very low fill factors (FF)<30% were measured for treated devices versus moderate 70-76% FF for untreated. The a-Si:H depositions for these devices were performed the following day after SiO₂ and interlayer treatment. Ellipsometry measurements (Cauchy fit) on polished wafers show a dielectric layer (in this example the dielectric layer was tunneling silicon dioxide) thickness increase from 1.54 nm prior to HMDS to 1.77 nm immediately after HMDS application to 1.97 nm the following day after being contained in a N₂ box. It is inferred that the FF drop is due to additional dielectric thickness adding to the equivalent oxide thickness, thereby decreasing tunneling probability.

In some embodiments, static vapor may result in uncertainty in the actual degree of functionalization, and therefore liquid immersion may be the preferred application for certain interlayers. For example, HMDS and/or 3-aminopropyltrimethoxysilane (APTMS) may be diluted in toluene, a solvent which is known to getter water, to prevent the interruption of interlayer adhesion. A steady increase in thickness with immersion time on polished silicon wafers for APTMS was shown, regardless of initial surface condition, while HMDS appears to terminate growth. Using APTMS as an interlayer precursor increases a growth mechanism where terminal amino groups of the attached molecule react with an incoming silane molecule trapping ammonia ions (NH₃⁺), and this process repeats to increase layer thickness (i.e., creating multilayers). Very low water contact angles were measured when applying APTMS on both textured and polished surface morphologies with both hydrogen-terminated and tunneling silicon dioxide dielectric layer surface state, implying extreme hydrophobicity. The analog occurs with HMDS with more hydrophobic behavior developing with immersion time regardless of surface morphology or initial condition, indicating a very high surface coverage of trimethylsilyl groups. Textured wafers with double sided dielectric layers of tunneling silicon dioxide were subjected to 1000 min immersion of both APTMS and HMDS to compare with untreated photovoltaic devices. One side of the photovoltaic device was isolated by first depositing a n/a-Si:H layer, then immersing this structure in the interlayer/toluene solution. Because these photovoltaic devices are inherently two-sided, the intent was to prevent thermal or plasma conditions of the first a-Si:H deposition from interacting with the second functionalized silicon dioxide dielectric layer surface. The baseline approach taken here required an initial i-layer (to maintain field passivation) to be deposited prior to masked p-layer for rear emitter configuration, since the p-layer capped with i-layer to exaggerate the blistering effect. Lifetime measurements prior to metallization show similar behavior with APTMS-treated iVocs slightly lower (684-692 mV) than HMDS treated (694-697 mV) and untreated (698-705 mV) devices.

The methods described herein may provide several benefits. First, using a interlayer to functionalize the oxide surface may allow for blistering control of the semiconductor poly-Si layer or precursor semiconductor a-Si:H layer to the wafer or oxide/buffer layer surface may mitigate or promote blistering as needed for the cell manufacture process. Second, using a interlayer to functionalize the dielectric layer surface may allow for dopant patterning induced by the patterning of interlayers on the cell surface (such as by the use of UV light) which may then be followed by selected adhesion of wet dopant inks or deposited dopant overlayers. Third, using a interlayer to functionalize the oxide surface may allow for the selective dopant or film to be used for several silicon photovoltaic technologies such as interdigitated back contact (IBC) cells, selective emitter formation in p-PERC cells, selective semiconductor poly-Si layer front surface coverage in front/back poly-Si/SiO₂ passivated cells (thin or no poly-Si in between the front metal fingers, and thick poly-Si underneath the metal fingers to enable damage-free screen printing), and/or patterning of a-Si:H and TCO layers in a-Si:H heterojunction cells. Fourth, using an interlayer to functionalize the oxide surface may allow for the patterning of metals on a silicon or other material solar cells using interlayers. Finally, using a interlayer to functionalize the dielectric layer surface may allow for selective adhesion of interlayers that contain dopants (such as B or P) directly to the cell surface, then capping them with another layer (such as a-Si:H) followed by a thermal drive-in.

Applying an interlayer does not degrade passivation. For example, Table 1 demonstrates that including an interlayer formed by HMDS does not degrade passivation and allows electronic transport. As shown in Table 1, the interlayer did not affect the iVoc of the structure. That is, it did not appear to create interface or bulk defects. Symmetric passivated contact structures on both preferred float zone (pFZ) and n-type Czochralski silicon textured (nCz) wafer types are shown in Table 1, both with HMDS (shown as “yes”) and without HMDS (shown as “no”) do not show significant passivation loss with an interlayer formed from HMDS. With the transfer length measurement (TLM) technique, 5.4 mΩ-cm² with an interlayer formed from HMDS and 38.2 mΩ-cm² without HMDS interlayer, showing that the application of the interlayer formed from HMDS does not impede electronic transport.

TABLE 1
Implied open-circuit voltage (iVoc) and
hexamethyldisilazane (HMDS) for two types of wafers.

| Wafer | HMDS? | iVoc (V) |
|---|---|---|
| Preferred Float Zone (pFZ) | Yes | 0.673 |
| pFZ | Yes | 0.674 |
| pFZ | Yes | 0.677 |
| pFZ | No | 0.684 |
| pFZ | No | 0.684 |
| n-type Czochralski silicon | Yes | 0.671 |
| textured (nCz txt) | | |
| nCz txt | Yes | 0.672 |
| nCz txt | Yes | 0.673 |
| nCz txt | No | 0.676 |
| nCz txt | No | 0.678 |
| nCz txt | No | 0.675 |

As shown in Table 2, electronic transport still took place through the passivated contact even with the interlayer applied. Table 2 shows the contact resistance of a pFZ silicon wafer, a pFZ silicon wafer with reactive ion etch (RIE), and an n-type Czochralski silicon textured (nCz) wafer. For each of the three types of wafers tested, one was treated with an interlayer precursor of HMDS and one was not treated. The results show that the presence of an interlayer did not reduce the electronic transport through the silicon wafer.

TABLE 2
Demonstration of Electronic Transport for Two Wafer Types.

| | pFZ | | | | nCz | |
|---|---|---|---|---|---|---|
| | | HMDS | No | No HMDS | | No |
| | HMDS | RIE | HMDS | RIE | HMDS | HMDS |
| Contact | 5.4 | 5.1 | 38.2 | 1632.2 | 40.2 | nonlinear |
| Resistance | | | | | | |
| (mΩ-cm²) | | | | | | |

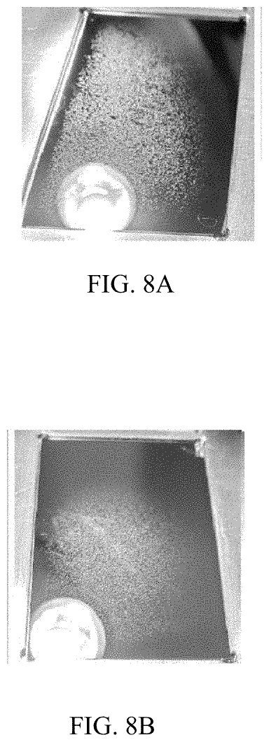

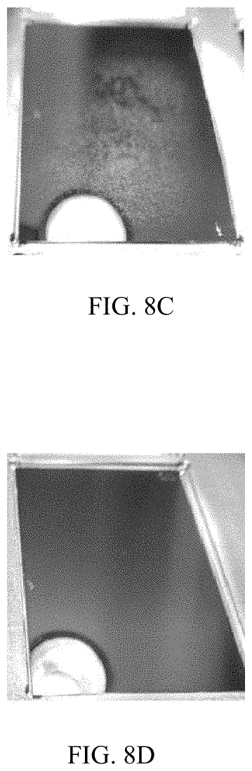

FIG. 8A is a photograph of a silicon wafer with a silicon dioxide dielectric layer that was treated with dimethylaminotrimethylsilane (DMATMS) as an interlayer precursor for 0 minutes. FIG. 8B is a photograph of a silicon wafer with a silicon dioxide dielectric layer that was treated with DMATMS as an interlayer precursor for 1 minute. FIG. 8C is a photograph of a silicon wafer with a silicon dioxide dielectric layer that was treated with DMATMS as an interlayer precursor for 10 minutes. FIG. 8D is a photograph of a silicon wafer with a silicon dioxide dielectric layer that was treated with DMATMS as an interlayer precursor for 100 minutes. FIGS. 8A-D show that longer soaking time in an interlayer precursor, such as DMATMS, promoted p/a-Si:H adhesion and reduced blistering. As the soaking time increased the p/a-Si:H adhesion did as well.

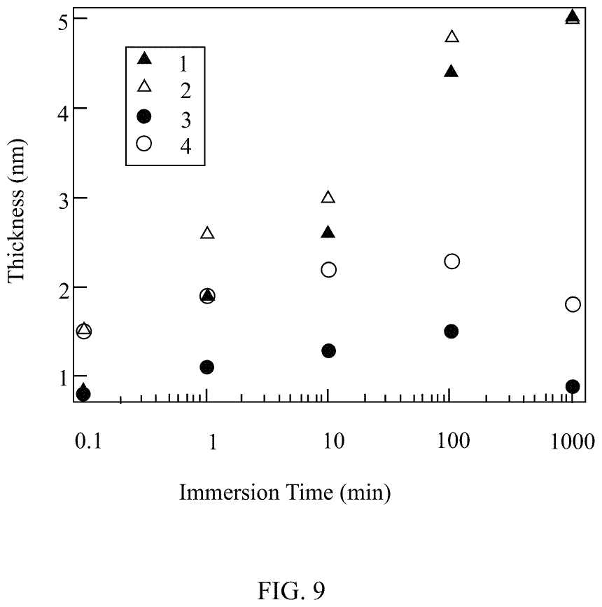

FIG. 9 illustrates the functionalized film thickness dependence on immersion time in an interlayer, according to some embodiments of the present disclosure. Data 1 shows hydrofluoric acid (HF) film thickness of a photovoltaic cell treated with an interlayer precursor of APTMS. Data 2 shows a dielectric layer of silicon dioxide film thickness of a photovoltaic cell treated with an interlayer precursor of APTMS. Data 3 shows a HF film thickness of a photovoltaic cell treated with an interlayer precursor of HMDS. Data 4 shows a dielectric layer of silicon dioxide film thickness of a photovoltaic cell treated with an interlayer precursor of HMDS. FIG. 9 indicates that there is a steady increase in thickness with immersion time on polished silicon wafers treated with an interlayer precursor of APTMS regardless of initial surface condition, while treating photovoltaic cells with an interlayer precursor of HMDS appears to terminate growth. Multilayers for photovoltaic cells treated with an interlayer precursor of HMDS are demonstrated due to a growth mechanism where terminal amino groups of the dielectric layer react with incoming silane molecules in the interlayer precursor, trapping ammonia ions, and repeating this process to increase the layer thickness.

References herein to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein, the terms “substantially” and/or “approximately” are used to indicate that exact values are not necessarily attainable. In some embodiments, the terms “substantially” and/or “approximately” are defined as approaching a specific numeric value or target within 20%, 15%, 10%, 5%, or within 1% of the value or target. In further embodiments, the terms “substantially” and/or “approximately” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments, the term “about” is used to indicate an uncertainty limit of less than or equal to ±20%, ±15%, ±10%, ±5%, or ±1% of a specific numeric target. In some embodiments, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing disclosure includes various examples set forth merely as illustration. The disclosed examples are not intended to be limiting. Modifications incorporating the spirit and substance of the described examples may occur to persons skilled in the art. These and other examples are within the scope of this disclosure and the following claims.

1. A device comprising, in order:
a silicon layer;
a dielectric layer in direct contact with the silicon layer;
an interlayer in direct contact with the dielectric layer; and
a precursor semiconductor layer; wherein:
the interlayer comprises:
a functional group, and
an impurity,
the dielectric layer comprises a dielectric material and the impurity,
the functional group is bonded to the dielectric layer, and
the precursor semiconductor layer comprises a semiconductor material and the impurity.

2. The device of claim 1, wherein the dielectric layer comprises a tunneling silicon dioxide.

3. The device of claim 1, wherein the functional group comprises trimethylsilyl.

4. The device of claim 1, wherein the precursor semiconductor layer comprises an amorphous silicon.

5. The device of claim 1, wherein the silicon layer is a preferred float zone silicon wafer.

6. The device of claim 1, wherein the silicon layer is an n-type Czochralski textured silicon wafer.

7. The device of claim 1, wherein the device has a contact resistivity of approximately 5 mΩ-cm².

8. The device of claim 1, wherein the impurity comprises at least one of carbon, nitrogen, or fluorine.

9. A method of forming a photovoltaic cell, the method comprising:
depositing a dielectric layer on a silicon layer;
applying a first precursor to the dielectric layer, resulting in an interlayer in direct contact with the dielectric layer;
applying a second precursor to the interlayer, resulting in a first layer in direct contact with the interlayer; and
annealing the dielectric layer, the interlayer, and the first layer, resulting in the first layer being transformed to a semiconductor layer; wherein:
the photovoltaic cell comprises the silicon layer, the dielectric layer, the interlayer, and the semiconductor layer.

10. The method of claim 9, wherein the dielectric layer comprises a tunneling silicon dioxide.

11. The method of claim 9, wherein the applying of the first precursor to the dielectric layer comprises
immersing the silicon layer in a first precursor.

12. The method of claim 9, wherein the applying of the first precursor to the dielectric layer comprises
suspending the silicon layer over the first precursor.

13. The method of claim 9, wherein the second precursor comprises silane, hydrogen, phosphine, and/or diborane gases.

14. The method of claim 13, wherein:
the first layer comprises an amorphous silicon, and
the semiconductor layer comprises a polycrystalline silicon.

15. The method of claim 9, wherein the first precursor comprises a silane.

16. The method of claim 15, wherein the silane comprises at least one of hexamethyldisilazane (HMDS), diemthylaminothrimethylsilane (DMATMS), or aminopropyltrimethoxysilane (APTMS).

17. The method of claim 9, further comprising:
diffusing an impurity into the dielectric layer; wherein:
the interlayer comprises a functional group and the impurity, and
the functional group bonds with the dielectric layer.

18. The method of claim 17, further comprising diffusing an impurity into the first layer.

19. The method of claim 17, wherein the impurity comprises at least one of carbon, nitrogen, or fluorine.

20. The method of claim 17, wherein the functional group comprises trimethylsilyl.
